(19) United States
(12) Patent Application Publication
(10) Pub. No.: US 2025/0343171 A1
(43) Pub. Date: Nov. 6, 2025

(54) ELECTRONIC DEVICE

(71) Applicant: Advanced Semiconductor Engineering Korea, Inc., Paju-Si (KR)

(72) Inventors: Jyhwan LEE, Paju-Si (KR); Hyunjin HAN, Paju-Si (KR); Hyoungjoon JIN, Paju-Si (KR)

(73) Assignee: Advanced Semiconductor Engineering Korea, Inc., Paju-Si (KR)

(21) Appl. No.: 18/656,568

(22) Filed: May 6, 2024

(51) Int. Cl. H01L 23/58; H01L 21/56; H01L 23/00; H01L 23/31; H01L 23/552; H01L 25/065; H01L 25/18

(52) U.S. Cl. CPC H01L 23/58; H01L 21/56; H01L 23/3121; H01L 23/552; H10D 1/042; H10D 1/714; H10D 1/716; H01L 24/48; H01L 25/0655; H01L 25/18; H01L 2224/48225

(57) ABSTRACT

An electronic device is provided. The electronic device includes a first electronic component, an encapsulant, a first capacitor, and a second capacitor. The encapsulant encapsulates the first electronic component. The first capacitor has a first depth and extends from an upper surface of the encapsulant. The second capacitor has a second depth, different from the first depth, and extends from the upper surface of the encapsulant.

### BACKGROUND

### 1. Field of the Disclosure

The present disclosure relates to an electronic device, and particularly to an electronic device including a passive component.

### 2. Description of the Related Art

A capacitor is commonly used in an electronic device to decouple one part of an electrical network (circuit) from another, such as to reduce parasitic inductance, reduce impedance and increase resonance frequency of the entire package. However, capacitors, such as deep trench capacitors (DTCs), would occupy a relatively large volume of a substrate, and the capacitance cannot be arbitrary adjusted after the design is fixed. Therefore, a new electronic device is required.

### SUMMARY

In some embodiments, an electronic device includes a first electronic component, an encapsulant, a first capacitor, and a second capacitor. The encapsulant encapsulates the first electronic component. The first capacitor has a first depth and extends from an upper surface of the encapsulant. The second capacitor has a second depth, different from the first depth, and extends from the upper surface of the encapsulant.

In some embodiments, an electronic device includes an electronic component, an encapsulant, and a first capacitor. The encapsulant encapsulates the electronic component. The first capacitor is accommodated by the encapsulant. The first capacitor extends along a first direction substantially orthogonal to an upper surface, spaced apart from the electronic component, of the encapsulant.

In some embodiments, an electronic device includes an electronic component, an encapsulant, and a plurality of vias. The encapsulant encapsulates the electronic component. The vias are within the encapsulant and configured to define a capacitor component.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an example of an electronic device according to some embodiments of the present disclosure.

FIG. 2A is a partial top view of an electronic device according to some embodiments of the present disclosure.

FIG. 2B is a cross-sectional view of FIG. 2A according to some embodiments of the present disclosure.

FIG. 3 illustrates a cross-sectional view of an example of an electronic device according to some embodiments of the present disclosure.

FIG. 4 illustrates a cross-sectional view of an example of an electronic device according to some embodiments of the present disclosure.

FIG. 5 is a partial enlarged view of the electronic device as shown in FIG. 4 according to some embodiments of the present disclosure.

FIG. 6 illustrates a layout of the carrier as shown in FIG. 4 according to some embodiments of the present disclosure.

FIG. 7 illustrates a top view of an example of an electronic device according to some embodiments of the present disclosure.

FIGS. 8A, 8B, and 8C illustrate various stages of an example of a method for manufacturing an electronic device according to some embodiments of the present disclosure.

FIGS. 9A, 9B, 9C, 9D, and 9E illustrate various stages of an example of a method for manufacturing an electronic device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

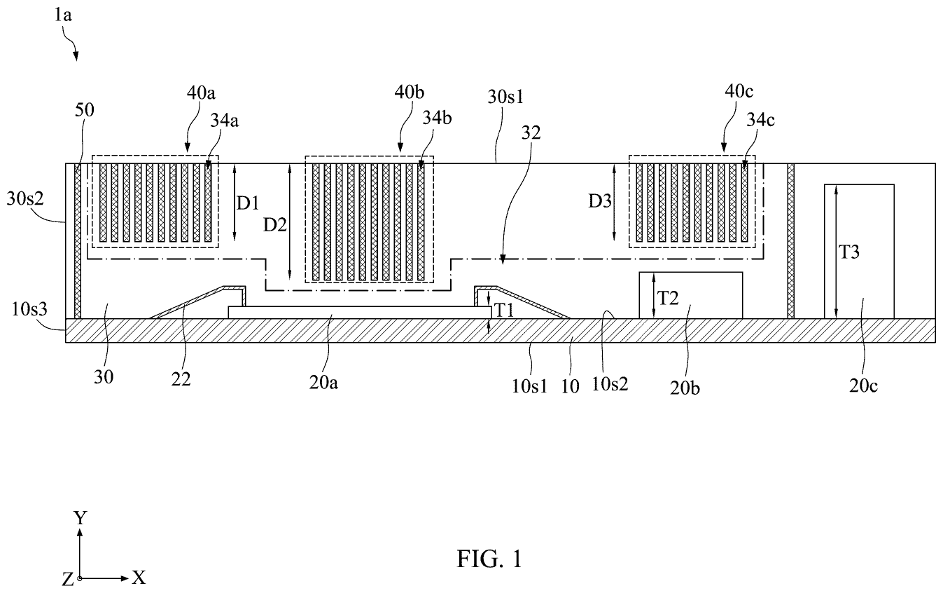

FIG. 1 illustrates a cross-sectional view of an example of an electronic device 1a according to some embodiments of the present disclosure. In some embodiments, the electronic device 1a may include a carrier 10, electronic components 20a, 20b, and 20c, an encapsulant 30, capacitor components 40a, 40b, and 40c, as well as conductive element 50.

The carrier 10 may be formed of, for example, a printed circuit board, such as a paper-based copper foil laminate, a composite copper foil laminate, or a polymer-impregnated glass-fiber-based copper foil laminate. The carrier 10 may include a redistribution structure or traces, for electrical connection between components. In some embodiments, the carrier 10 can be replaced by other suitable carriers, such as a lead frame. The carrier 10 may have a surface 10s1 (or a lower surface), a surface 10s2 (or an upper surface) opposite to the surface 10s1, and a surface 10s3 (or a lateral surface) extending between the surface 10s1 and surface 10s2. In some embodiments, electrical connectors (not shown), such as solder balls, may be disposed on or under the surface 10s1 of the carrier 10 to be connected to an external device.

The electronic components 20a to 20c may be disposed on or over the surface 10s2 of the carrier 10. It should be noted that the quantity of electronic components shown in FIG. 1 is for illustrative purposes only, and the present disclosure is not intended to be limiting. Each of the electronic components 20a to 20c may include a semiconductor die or a chip, such as a logic die (e.g., application processor (AP), system-on-a-chip (SoC), central processing unit (CPU), graphics processing unit (GPU), microcontroller, etc.), a memory die (e.g., dynamic random access memory (DRAM) die, static random access memory (SRAM) die, etc.), a radio frequency (RF) die, a sensor die, a micro-electro-mechanical-system (MEMS) die, a signal processing die (e.g., digital signal processing (DSP) die), a front-end die (e.g., analog front-end (AFE)dies) or other active components.

In some embodiments, the electronic components 20a to 20c may have different thicknesses. For example, the electronic component 20a may have a thickness T1, the electronic component 20b may have a thickness T2, and the electronic component 20c may have a thickness T3. The thickness T1 may be less than the thickness T2. The thickness T2 may be less than the thickness T3.

Each of the electronic components 20a to 20c may be electrically connected to the carrier 10. For example, the electronic device 1a may include electrical connectors 22 configured to electrically connect the electronic component 20a and the carrier 10. The electrical connector 22 may include, for example, a conductive wire. In some embodiments, the electronic component 20b (or electronic component 20c) may be attached to the carrier 10 by a flip-chip technique. In this condition, the electronic component 20b (or electronic component 20c) may be attached to the carrier 10 by electrical connectors, such as solder materials.

In some embodiments, the encapsulant 30 may be disposed on or over the surface 10s2 of the carrier 10. The encapsulant 30 may encapsulate the electronic components 20a to 20c. The encapsulant 30 may include insulation or dielectric material. In some embodiment, the encapsulant 30 may be made of molding material that may include, for example, a novolac-based resin, an epoxy-based resin, a silicone-based resin, or other another suitable encapsulant. The encapsulant 30 may include a molding compound which is formed by a molding technique, such as compression molding, injection molding, or transfer molding. Suitable fillers may also be included, such as powdered SiO₂. The encapsulant 30 may have a surface 30s1 (or an upper surface) spaced apart from the carrier 10 and a surface 30s2 (or a lateral surface) connected to the surface 30s1. In some embodiments, the surface 30s2 of the encapsulant 30 may be substantially aligned with the surface 10s3 of the carrier 10.

In some embodiments, the encapsulant 30 may define a clearance region 32. The clearance region 32 may be an imaginary region over the electronic component 20a, 20b, and/or 20c. The clearance region 32 is configured to define a minimum space or distance, where no other components (e.g., electronic components, traces, vias, or the like) are disposed, over an upper surface of the electronic component 20a, 20b, and/or 20c. The profile of the clearance region 32 may be determined by the thickness and the distribution of the electronic components 20a to 20c as well as other components.

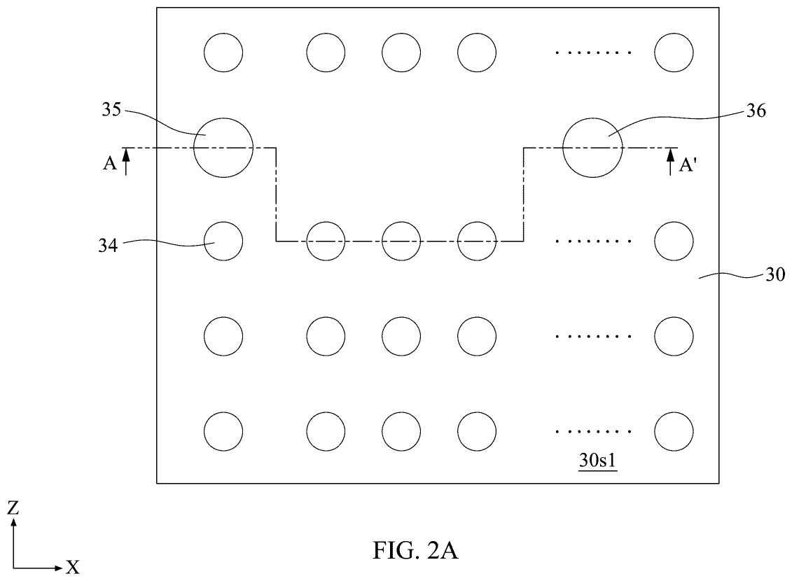

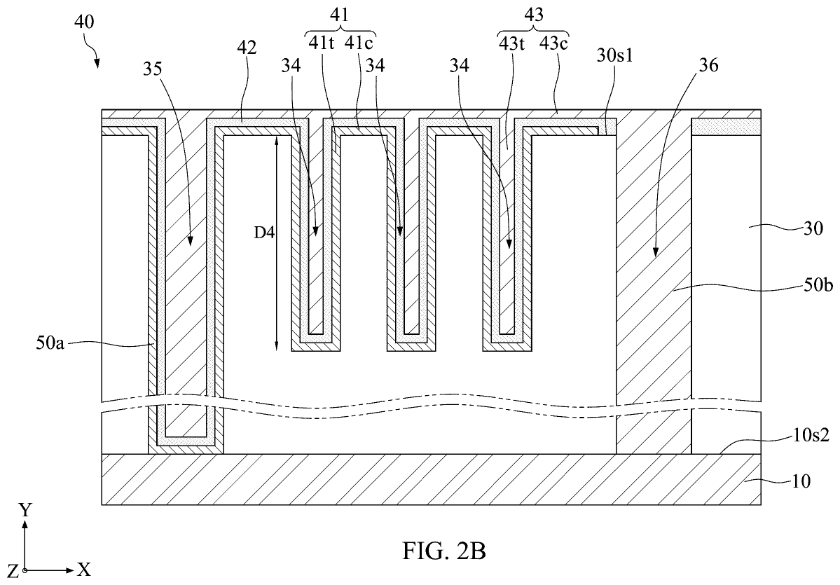

In some embodiments, each of the capacitor components 40a to 40c may be disposed within the encapsulant 30. In some embodiments, each of the capacitor components 40a to 40c may extend from the surface 30s1 of the encapsulant 30. Each of the capacitor components 40a to 40c may be disposed within the trenches, recessed from the surface 30s1, of the encapsulant 30. For example, the encapsulant 30 defines trenches 34a, trenches 34b, and trenches 34c. The capacitor component 40a is at least partially disposed within the trenches 34a. The capacitor component 40b is at least partially disposed within the trenches 34b. The capacitor component 40c is at least partially disposed within the trenches 34c. In some embodiments, each of the capacitor components 40a to 40c may be configured to stabilize, adjust, and/or regulate power. The capacitor components 40a to 40c may include a multielectrode tunable capacitor (MTC), deep trench capacitor (DTC), a multi-layer ceramic capacitor (MLCC) or other capacitors. It should be noted that the detailed structure of the capacitor component (e.g., the capacitor components 40a to 40c) are omitted for brevity, which will be described in detail in FIG. 2A and FIG. 2B.

In some embodiments, the capacitor components 40a to 40c may have different depths. For example, the capacitor component 40a may have a depth D1, the capacitor component 40b may have a depth D2, and the capacitor component 40c may have a depth D3. The depth D1 may be unequal to the depth D2. The depth D2 may be unequal to the depth D3. In this disclosure, the depth of a capacitor may be defined by a depth of the trench which is configured to accommodate said capacitor. For example, the depth D1 may be substantially equal to the depth of the trench 34a of the encapsulant 30.

The capacitor component 40a may be free from overlapping the electronic component (e.g., the capacitor components 40a to 40c) along the Y direction. In some embodiments, the capacitor component 40b may overlap the electronic component 20a along the Y direction. In some embodiments, the capacitor component 40c may overlap the electronic component 20b along the Y direction. In some embodiments, no capacitor component is disposed over the electronic component 20c. In some embodiments, the capacitor components 40a to 40c may be disposed over the carrier 10 and beyond of the clearance region 32, which effectively utilizes the area of the encapsulant 30. The depth of the capacitor components 40a to 40c may be determined based on the requirements for design. In some embodiments, the location of the capacitor components 40a to 40c may be determined based on the layout of the components (e.g., the electronic component 20a or electrical connector 22) over the carrier 10. For example, the capacitor component with a greater depth may be disposed over the electronic component with a smaller thickness.

The conductive element 50 may be disposed on or over the surface 10s2 of the carrier 10. The conductive element 50 may be electrically connected to the carrier 10, The conductive element 50 may penetrate the encapsulant 30. In some embodiments, the conductive element 50 may be configured to electrically connect a capacitor (e.g., the capacitor component 40a) and an electronic component (e.g., the electronic component 20a) through the carrier 10. The conductive element 50 may include a conductive pillar, which may include a seed layer and a conductive layer over the seed layer. The conductive element 50 may include, for example, copper (Cu), gold (Au), silver (Ag), nickel (Ni), palladium (Pd), another metal(s) or alloy(s), or a combination of two or more thereof.

FIG. 2A is a top view of the electronic device according to some embodiments of the present disclosure. In some embodiments, the encapsulant 30 may define a plurality of trenches 34. The trench 34 may be recessed from the surface 30s1 of the encapsulant 30. The trench 34 may be configured to accommodate a via structure including electrodes and capacitor dielectric of a capacitor component. In some embodiments, the trenches 34 may define an N×N array. In some embodiments, the encapsulant 30 may define trenches 35 and 36. The electrodes within the trenches 35 and 36 may be electrically to different power supplies.

FIG. 2B is a cross-sectional view along line A-A′ of the electronic device as shown in FIG. 2A. In some embodiments, the capacitor component 40 shown in FIG. 2B may be a part of the capacitor component 40a, 40b, or 40c. In some embodiments, the capacitor component 40 may include an electrode 41, a capacitor dielectric 42, and an electrode 43.

The electrode 41 (or a first electrode) may be disposed within the trench 34. The electrode 41 may be disposed on and contact the sidewall of the trench 34. The electrode 41 may be disposed on and contact the bottom of the trench 34. The electrode 41 may be formed by sputtering titanium and copper (Ti/Cu) or a titanium-tungsten alloy (TiW). In some embodiments, the electrode 41 may be formed by multiple conductive layers including a seed layer(s) (e.g., Ti). In some embodiment, the electrode 41 may be formed by filling the trench 34 by a conductive material(s), such as conductive paste (e.g., Cu paste or Ag paste). In some embodiments, the electrode 41 may be formed by electroless plating of Ni or Cu. In some embodiments, the electrode 41 may include via parts 41t within the trench 34 and a connection part 41c over the surface 30s1 of the encapsulant 30. The via part 41t may extend along the Y direction. The connection part 41c may connect multiple via parts 41t. The connection part 41c may be exposed by the surface 30s1 of the encapsulant 30.

The capacitor dielectric 42 (or dielectric layer) may be conformally disposed on the electrode 41. In some embodiments, the capacitor dielectric 42 may be disposed on or over the surface 30s1 of the encapsulant 30. In some embodiments, the capacitor dielectric 42 may be disposed within the trench 34. The capacitor dielectric 42 may include, for example, an organic material, a solder mask, a polyimide (PI), an Ajinomoto build-up film (ABF), one or more molding compounds, one or more pre-impregnated composite fibers (e.g., a pre-preg material), a borophosphosilicate glass (BPSG), a silicon oxide, a silicon nitride, a silicon oxynitride, an undoped silicate glass (USG), any combination thereof, or the like. In some examples, the capacitor dielectric 42 may include, for example, an inorganic material, such as a silicon-oxide (SiOx), a silicon-nitride (SiNx), a tantalum oxide (TaOx) or the like.

The electrode 43 (or a second electrode) may be disposed on the capacitor dielectric 42. The material of the electrode 43 may be the same as or similar to the electrode 41. The electrode 43 may be spaced apart from the electrode 41 by the capacitor dielectric 42. In some embodiments, the electrode 43 may include via parts 43t within the trench 34 and a connection part 43c over the surface 30s1 of the encapsulant 30. The via part 43t may extend along the Y direction. The connection part 43c may connect multiple via parts 43t. The connection part 43c may be exposed by the surface 30s1 of the encapsulant 30. The connection part 43c may be disposed over the connection part 41c.

In some embodiments, the electrode 43 may overlap the electrode 41 along the X direction. In some embodiments, the via part 41t may overlap the via part 43t along the X direction. In some embodiments, the electrode 43 may overlap the electrode 41 along the Y direction. In some embodiments, the via part 41t may overlap the via part 43t along the Y direction. In some embodiments, the via part 41t may overlap the capacitor dielectric 42 along the X direction. In some embodiments, the via part 41t may overlap the capacitor dielectric 42 along the Y direction. In some embodiments, the connection part 41c may overlap the capacitor dielectric 42 along the Y direction. In some embodiments, the connection part 43c may overlap the capacitor dielectric 42 along the Y direction. In some embodiments, the electrode 41 and electrode 43 may collectively define a via (or via structure) within the trench 34, which may be regarded as a part of the capacitor component 40. In some embodiments, the electrode 41 may be a positive node (or a positive electrode) of the capacitor component 40, and the electrode 43 may be a negative node (or a negative electrode) of the capacitor component 40.

In some embodiments, the encapsulant 30 may define a trench 35 and a trench 36 for accommodating conductive element 50a and conductive element 50b. Each of the trench 35 and the trench 36 may set back from the surface 30s1 of the encapsulant 30. In some embodiments, the trenches 35 and 36 may fully penetrate the encapsulant 30. In some embodiments, the dimension (e.g., the aperture or width) of the trench 35 (or trench 36) may be greater than that of the trench 34. The surface 10s2 of the carrier 10 may be exposed by the trench 35 (or trench 36).

A conductive element 50a may be disposed within the trench 35. The conductive element 50a may be configured to electrically connect the electrode 41 and a first power from the carrier 10. A conductive element 50b may be disposed within the trench 36. The conductive element 50b may be configured to electrically connect the electrode 43 and a second power, different from the first power, from the carrier 10. In some embodiments, the electrode 41, the capacitor dielectric 42, and the electrode 43 may be disposed within the trench 35 and built a portion of the capacitor component 40. In some embodiments, the electrode 41 may be located beyond the trench 36. In some embodiments, the capacitor dielectric 42 may be located beyond the trench 36. The electrode 43 may be disposed on and contact the sidewall of the trench 36. Although FIG. 2B illustrates that the electrode 43 completely fill the trench 36, the electrode 43 may be conformally disposed on the trench 36 and define a recess. In some embodiments, the depth D4 may indicate the depth of the trench 34, and may be defined, for example, by a distance between the bottom of the via part 41t and the lower surface of the connection part 41c.

In this embodiment, the capacitance of the capacitor component can be modified by adjusting the depth and the quantity of the trench. Further, the capacitor component may be disposed within the encapsulant after determining a clearance region.

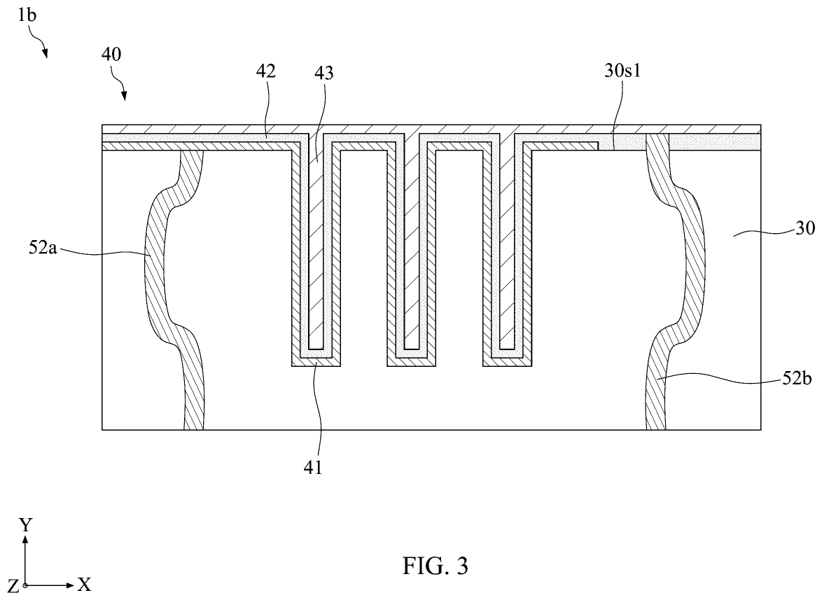

FIG. 3 illustrates a cross-sectional view of an example of an electronic device 1b according to some embodiments of the present disclosure. The electronic device 1b of FIG. 3 has a structure similar to that of the electronic device 1a, with differences outlined below.

In some embodiments, the electronic device 1b may include conductive elements 52a and 52b. The conductive element 52a may be configured to electrically connect the electrode 41 and the carrier 10 as shown in FIG. 1. The conductive element 52b may be configured to electrically connect the electrode 43 and the carrier 10 as shown in FIG. 1. In some embodiments, each of the conductive elements 52a and 52b may include a conductive wire. In some embodiments, the conductive wire may be a bonding wire, which may include a straight-shaped profile or a curved-shaped profile which is not perpendicular to the surface 10s2 of the carrier 10 in a cross-sectional view. In some embodiments, the top of the conductive element 52a may be exposed from the surface 30s1 of the encapsulant 30. In some embodiments, the conductive element 52b may penetrate the capacitor dielectric 42. In some embodiments, a portion of the conductive element 52b may protrude over the surface 30s1 of the encapsulant 30. In some embodiments, the top of the conductive element 52b may be at a level higher than that of the top of the electrode 41. In some embodiments, the top of the conductive element 52b may be at a level higher than that of the top of the conductive element 52a.

When the conductive elements 52a and 52b are formed, a mask may cover the conductive element 52b to prevent short between the conductive element 52b and the electrode 41 which is subsequently formed. After the electrode 41 is formed. The mask is removed to expose the conductive element 52b.

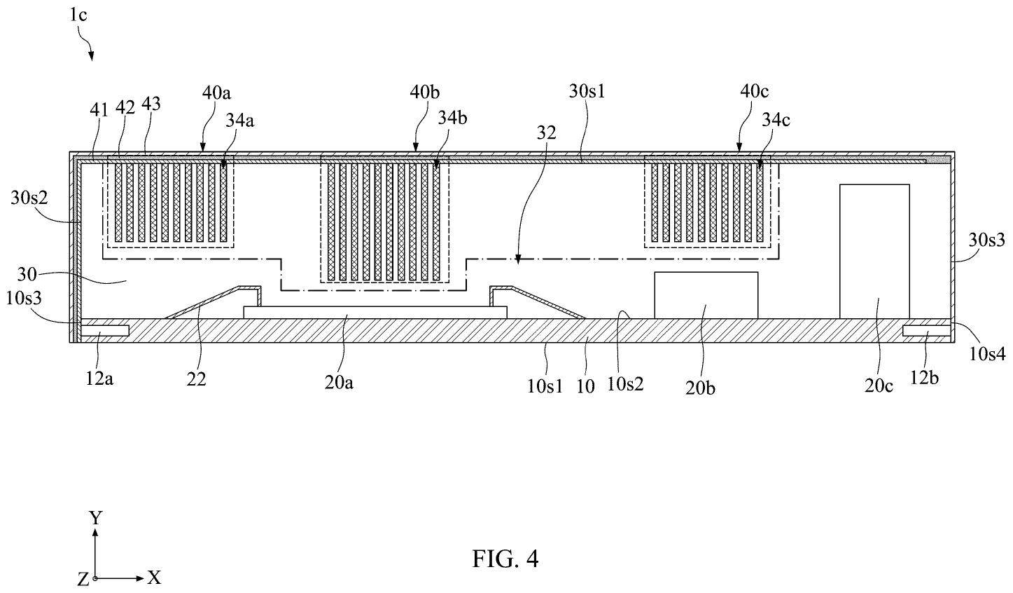

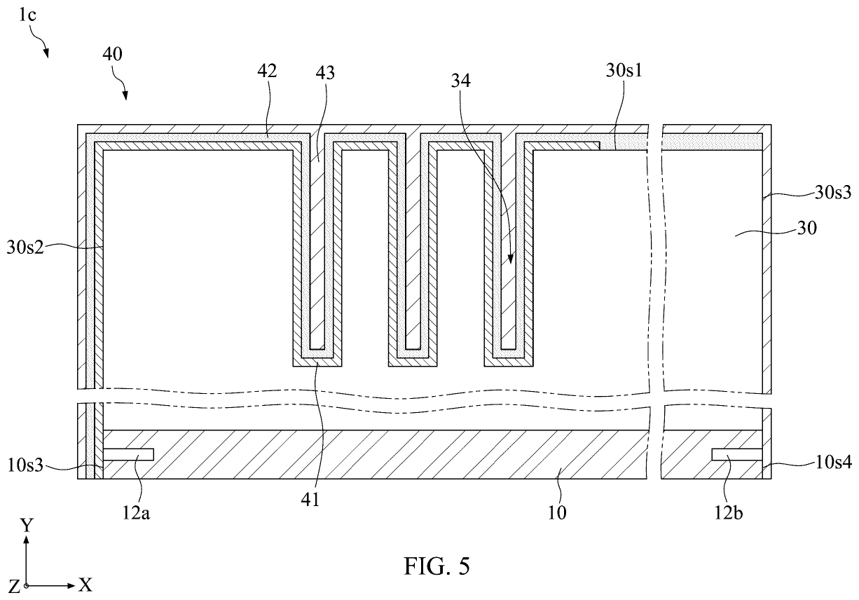

FIG. 4 and FIG. 5 illustrate an example of an electronic device 1c according to some embodiments of the present disclosure. The electronic device 1c has a structure similar to that of the electronic device 1a, with differences outlined below. It should be noted that the profiles of the electrode 41, the capacitor dielectric 42, and the electrode 43 are simplified for brevity. Each of the electrode 41, the capacitor dielectric 42, and the electrode 43 may extend into the trenches 34a (or 34b or 34c). For example, as shown in FIG. 5, the electrode 41, the capacitor dielectric 42, and the electrode 43 may extend into the trenches 34.

In some embodiments, the electrode 41 of the capacitor component 40a (or 40b or 40c) may be disposed on the surface 30s2 of the encapsulant 30. In some embodiments, the electrode 41 may be disposed on the surface 10s3 of the carrier 10. The electrode 41 may be electrically connected to a terminal 12a, which may be configured to supply a first power, of the carrier 10.

In some embodiments, the capacitor dielectric 42 may be disposed on the surface 30s2 of the encapsulant 30. In some embodiments, the capacitor dielectric 42 may be disposed on the surface 10s3 of the carrier 10. The capacitor dielectric 42 may overlap the electrode 41 along the X direction.

In some embodiments, the electrode 43 of the capacitor component 40a (or 40b or 40c) may be disposed on the surface 30s2 of the encapsulant 30. In some embodiments, the electrode 43 of the capacitor component 40a (or 40b or 40c) may be disposed on a surface 30s3, different from the surface 30s2, of the encapsulant 30. In some embodiments, the electrode 43 may be in contact with the surface 30s3 of the encapsulant 30. In some embodiments, the electrode 43 may be disposed on the surface 10s3 of the carrier 10. In some embodiments, the electrode 43 may overlap the electrode 41 along the X direction. In some embodiments, the electrode 43 may overlap the capacitor dielectric 42 along the X direction. The electrode 43 may be disposed on a surface 10s4 (or a lateral surface) of the carrier 10. The electrode 43 may be electrically connected to a terminal 12b, which may be configured to supply a second power different form the first power, of the carrier 10.

In this embodiment, the electrode 41 (or electrode 43) may function as a shielding layer, which can be used to provide an electromagnetic interference (EMI) protection for the electronic components 20a to 20c.

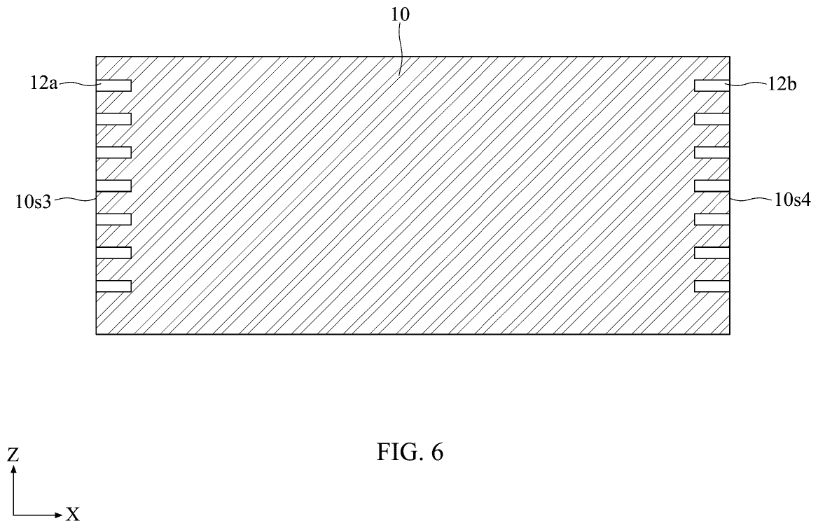

FIG. 6 illustrates a layout of the carrier 10 as shown in FIG. 4 according to some embodiments of the present disclosure. In some embodiments, the carrier 10 may include a plurality of terminals exposed by the surface 10s3 of the carrier 10. In some embodiments, the carrier 10 may include a plurality of terminals 12b exposed by the surface 10s4 of the carrier 10. In some embodiments, at least one of the terminals 12a may be connected to the electrode 41 as shown in FIG. 4. In some embodiments, a portion of the terminals 12a may be electrically isolated from the electrode 41. In some embodiments, at least one of the terminals 12b may be connected to the electrode 43 as shown in FIG. 4. In some embodiments, a portion of the terminals 12b may be electrically isolated from the electrode 43.

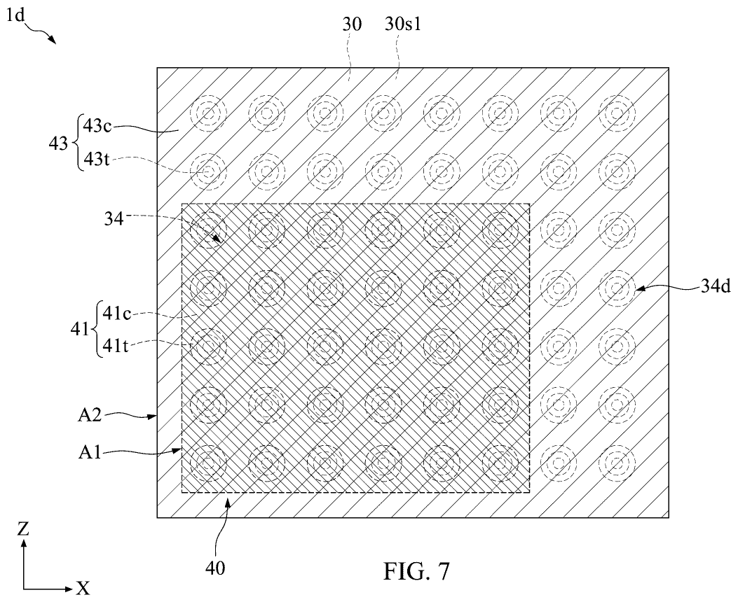

FIG. 7 illustrates a top view of an example of an electronic device 1d according to some embodiments of the present disclosure. The encapsulant 30 may define a plurality of trenches 34 which are arranged as an N & N array. The electrode 41 may define an area A1 over the surface 30s1 of the encapsulant 30. The electrode 43 may define an area A2 over the surface 30s1 of the encapsulant 30. In some embodiments, the area A1 is not equal to the area A2. In some embodiments, the area A2 may be greater than the area A1. In some embodiments, a portion of the connection part 43c of the electrode 43 is free from overlapping the connection part 41c of the electrode 41 in a top view. In some embodiments, some of the trenches 34 (e.g., trenches 34d) may be exposed by the connection part 41c. The connection part 41c does not cover the trench 34d. In this embodiment, the trench 34d may function as a dummy via which does not build a portion of the capacitor component 40. In some embodiments, the depth of the trench 34d may be substantially the same as that of the trench 34. In this embodiment, the capacitance of the capacitor component 40 may be modified by the area A1, over the surface 30s1, of the electrode 41.

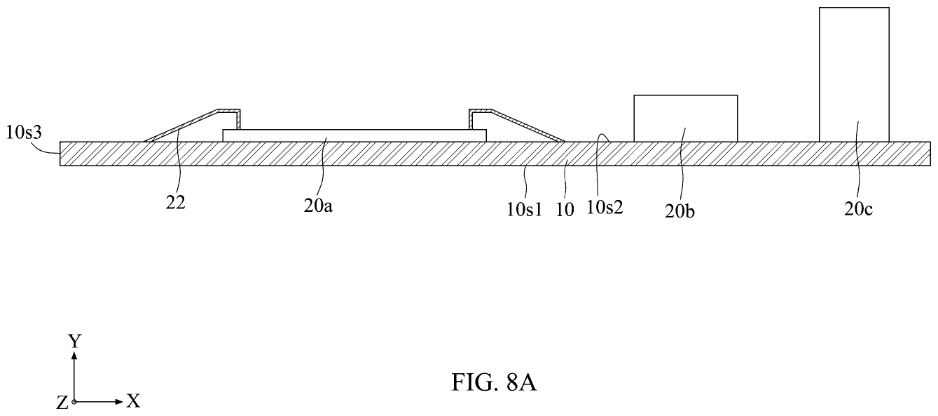

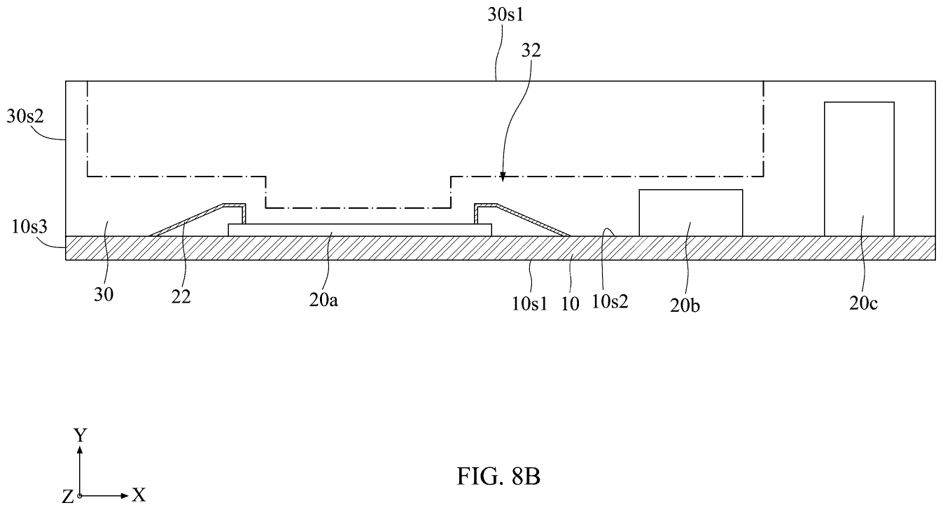

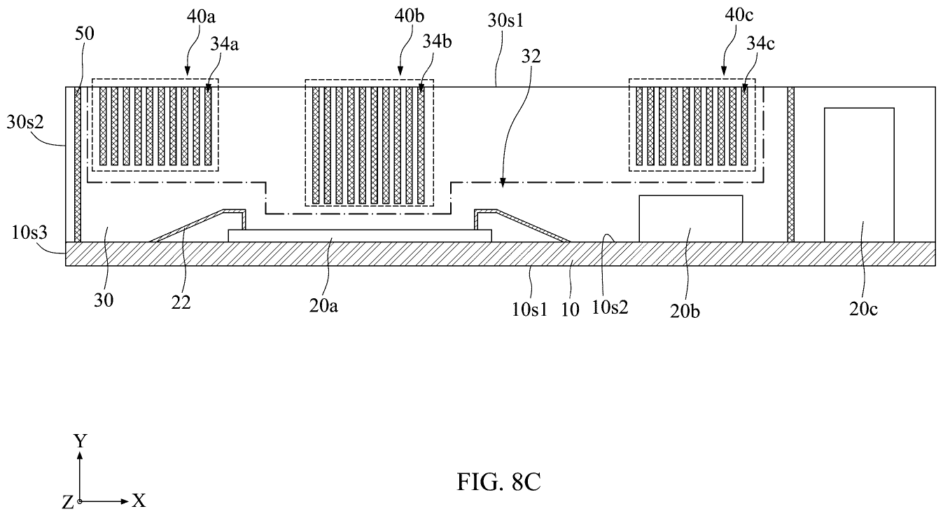

FIGS. 8A, 8B, and 8C illustrate various stages of an example of a method for manufacturing an electronic device according to some embodiments of the present disclosure.

Referring to FIG. 8A, the carrier 10 may be provided. The electronic components 20a to 20c may be attached to the surface 10s2 of the carrier 10 by a suitable technique.

Referring to FIG. 8B, the encapsulant 30 may be formed on the surface 10s2 of the carrier 10. The encapsulant 30 may encapsulate the electronic components 20a to 20c. The clearance region 32 may be determined.

Referring to FIG. 8C, the trenches 34a, 34b, and 34c may be defined and beyond the clearance region 32. The capacitor components 40a to 40c may be formed within the encapsulant 30. The conductive elements 50 may be formed. As a result, an electronic device (e.g., the electronic device 1a) may be produced.

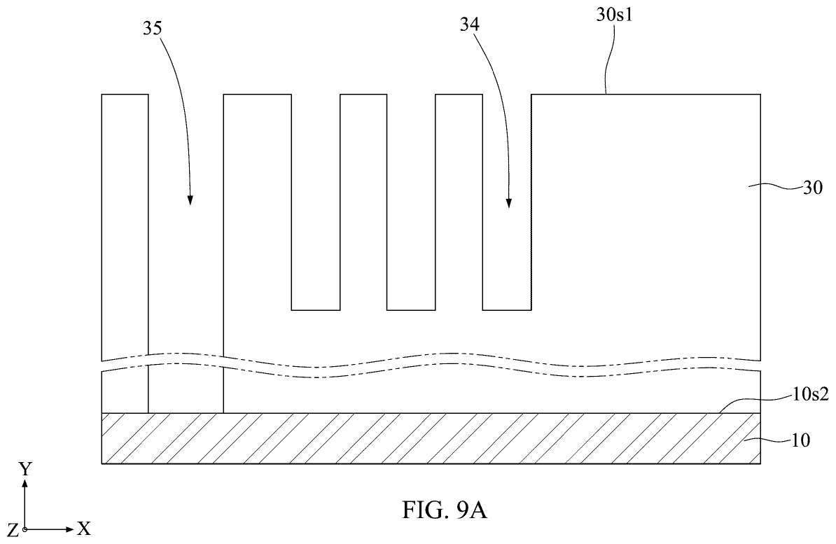

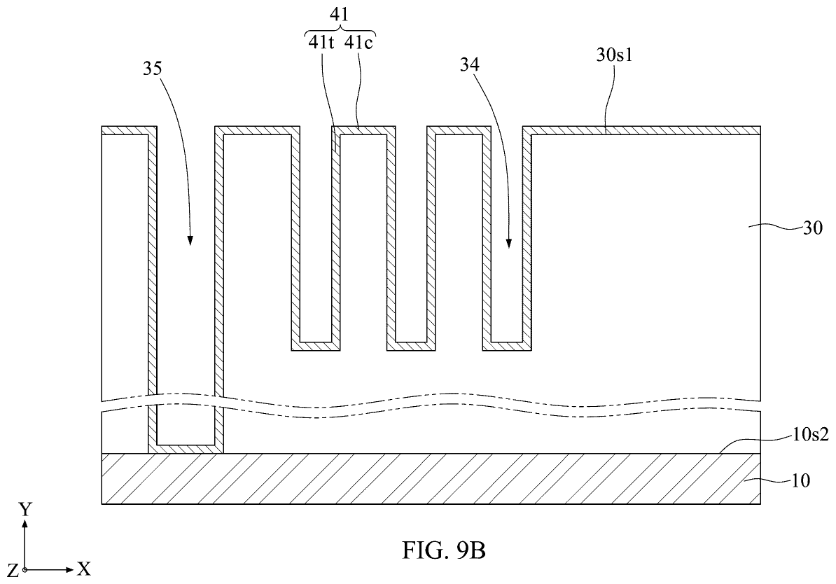

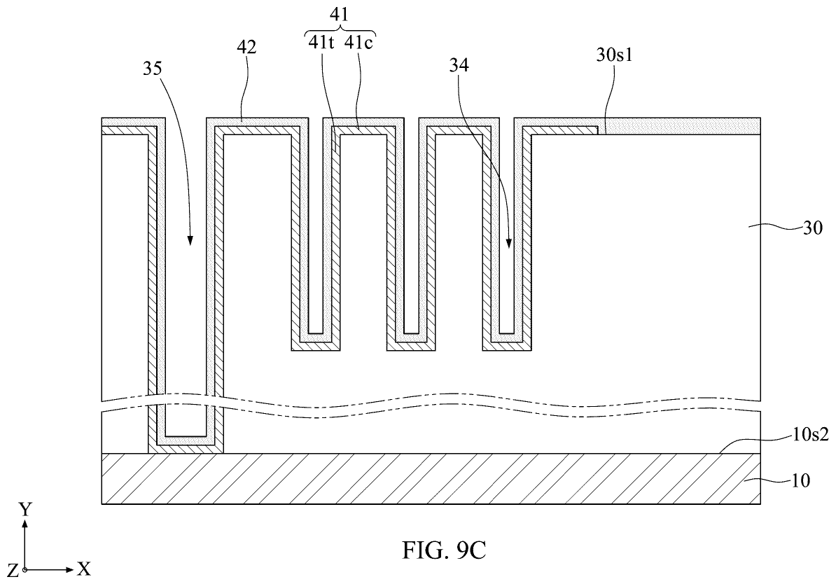

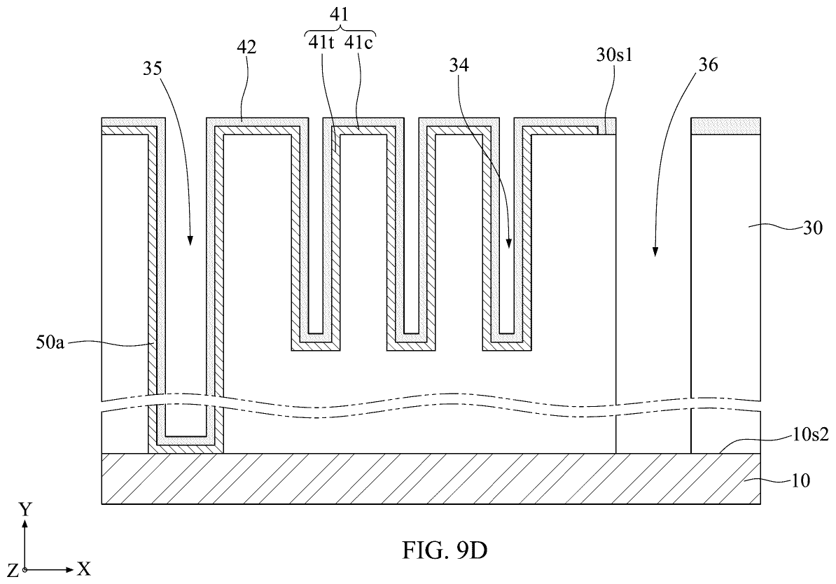

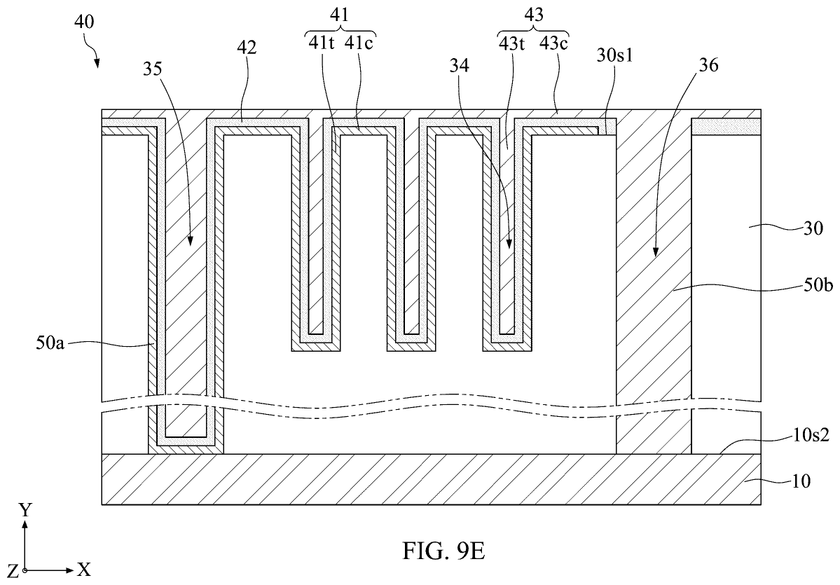

FIGS. 9A, 9B, 9C, 9D, and 9E illustrate various stages of an example of a method for manufacturing an electronic device according to some embodiments of the present disclosure. FIGS. 9A to 9E illustrate the processes of forming a part of a capacitor. In some embodiments, FIG. 9A illustrates a stage subsequent to the stage of FIG. 8B.

Referring to FIG. 9A, the trenches 34 and the trench 35 may be formed. In some embodiments, the trenches 34 and the trench 35 may be formed by, for example, a laser ablation technique or other suitable techniques.

Referring to FIG. 9B, the electrode 41 may be formed. The electrode 41 may be formed within the sidewall of the trenches 34 and the trench 35. The electrode 41 may be formed on the bottom of the trench 34. The electrode 41 may be formed on the surface 10s2 of the carrier 10. In some embodiments, the electrode 41 may be formed by a sputter technique, an electroplating technique, or other suitable techniques.

Referring to FIG. 9C, the electrode 41 over the surface 30s1 may be patterned. A portion of the electrode 41 over the surface 30s1 may be removed. The capacitor dielectric 42 may be formed on the electrode 41 and on the surface 30s1 of the encapsulant 30. In some embodiments, the capacitor dielectric 42 may be formed by a coating technique, a deposition technique, or other suitable techniques.

Referring to FIG. 9D, the trench 36 may be formed to penetrate the capacitor dielectric 42 and the encapsulant 30. A portion of the capacitor dielectric 42 and the encapsulant 30 may be removed. In some embodiments, the trench 36 may be formed by, for example, a laser ablation technique or other suitable techniques.

Referring to FIG. 9E, the electrode 43 may be formed within the sidewall of the trenches 34, 35, and 36. The electrode 43 may be formed on the bottom of the trench 34. The electrode 43 may be formed on the surface 10s2 of the carrier 10. In some embodiments, the electrode 43 may be formed by a sputter technique, an electroplating technique, or other suitable techniques.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to +10% of that numerical value, such as less than or equal to +5%, less than or equal to +4%, less than or equal to +3%, less than or equal to +2%, less than or equal to +1%, less than or equal to +0.5%, less than or equal to +0.1%, or less than or equal to +0.05%. For example, two numerical values can be deemed to be “substantially” the same or equal if a difference between the values is less than or equal to +10% of an average of the values, such as less than or equal to +5%, less than or equal to +4%, less than or equal to +3%, less than or equal to +2%, less than or equal to +1%, less than or equal to +0.5%, less than or equal to +0.1%, or less than or equal to +0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a first electronic component;
an encapsulant encapsulating the first electronic component;
a first capacitor having a first depth extending from an upper surface of the encapsulant; and
a second capacitor having a second depth, different from the first depth, extending from the upper surface of the encapsulant.

2. The electronic device of claim 1, wherein the first electronic component vertically overlaps the first capacitor.

3. The electronic device of claim 1, further comprising:
a second electronic component having a thickness different from that of the first electronic component.

4. The electronic device of claim 3, wherein the second electronic component vertically overlaps the second capacitor.

5. The electronic device of claim 1, wherein a first electrode of the first capacitor is exposed by the upper surface of the encapsulant.

6. The electronic device of claim 1, wherein the encapsulant defines a trench accommodating a first electrode and a second electrode of the first capacitor.

7. The electronic device of claim 6, wherein the first electrode of the first capacitor extends from the upper surface of the encapsulant to a bottom of the trench.

8. The electronic device of claim 6, wherein the first electrode comprises a first portion over the upper surface of the encapsulant, and the second electrode comprises a second portion over the upper surface of the encapsulant.

9. The electronic device of claim 7, wherein the first electrode further comprises a third portion extending along a lateral surface connected to the upper surface of the encapsulant.

10. The electronic device of claim 8, further comprising:
a carrier supporting the first electronic component; and
a conductive wire electrically connecting the first electronic component and the carrier.

11. An electronic device, comprising:
an electronic component;
an encapsulant encapsulating the electronic component; and
a first capacitor accommodated by the encapsulant, wherein the first capacitor extends along a first direction substantially orthogonal to an upper surface, spaced apart from the electronic component, of the encapsulant, and the first capacitor overlaps the electronic component along the first direction.

12. The electronic device of claim 11, wherein the encapsulant defines a trench extends along the first direction and accommodating the first capacitor.

13. The electronic device of claim 12, wherein the first capacitor comprises a deep trench capacitor.

14. The electronic device of claim 11, further comprising:
a carrier supporting the electronic component;
a first conductive wire connecting a first electrode of the first capacitor and the carrier; and
a second conductive wire connecting a second electrode of the first capacitor and the carrier, wherein a top of the first conductive wire is in a level different from a level of a top of the second conductive wire.

15. The electronic device of claim 14, wherein the top of the second conductive wire is protruded from the upper surface of the encapsulant.

16. An electronic device, comprising:
an electronic component;
an encapsulant encapsulating the electronic component; and
a plurality of vias within the encapsulant and configured to define a capacitor component.

17. The electronic device of claim 16, wherein the plurality of vias comprise a first electrode and a second electrode spaced apart from the first electrode by a dielectric layer.

18. The electronic device of claim 17, wherein a top of the first electrode is at a level different from a level of a top of the second electrode with respect to an upper surface of the encapsulant.

19. The electronic device of claim 17, wherein the first electrode and the second electrode overlap a lateral surface of the encapsulant.

20. The electronic device of claim 16, further comprising:
a carrier supporting the encapsulant, wherein a first via of the plurality of vias comprises a first electrode extending from an upper surface of the encapsulant to the carrier, a second via of the plurality of vias comprises a second electrode extending from the upper surface of the encapsulant to the carrier, and the first electrode is electrically coupled to the second electrode.
